(19) United States
(12) Patent Application Publication
(10) Pub. No.: US 2009/0170024 A1
(43) Pub. Date: Jul. 2, 2009

(54) Method of Patterning a Substrate, Photosensitive Layer Stack and System for Lithography

(76) Inventors: Mario Hennig, Dresden (DE); Rainer Pforr, Dresden (DE); Jens Reichelt, Dresden (DE)

Correspondence Address: SLATER & MATSIL, L.L.P., 17950 PRESTON ROAD, SUITE 1000, DALLAS, TX, 75252, US

(21) Appl. No.: 11/968,015

(22) Filed: Dec. 31, 2007

(51) Int. Cl. G03C 1/00; G03F 7/26; G03B 27/34

(52) U.S. Cl. 430/270.1; 430/322; 355/56

(57) ABSTRACT

A photosensitive layer stack, lithographic systems and methods of patterning a substrate are disclosed having a patterning layer and a photochromic layer with an absorption switching from transmissive to absorptive upon exposure.

### TECHNICAL FIELD

Embodiments of the invention relate to methods of patterning a substrate, photosensitive layer stack and system for lithography.

### BRIEF DESCRIPTION OF THE DRAWINGS

In the accompanying drawings:

FIGS. 1A and 1B illustrate a photosensitive layer stack according to embodiments of the invention;

FIG. 2A illustrates a substrate in a side view during processing according to an embodiment of the invention;

FIG. 2B illustrates a substrate in a top view during processing according to an embodiment of the invention;

FIG. 2C illustrates a substrate in a side view during processing according to an embodiment of the invention;

FIG. 2D illustrates a substrate in a side view during processing according to an embodiment of the invention;

FIG. 2E illustrates a substrate in a top view during processing according to an embodiment of the invention;

FIG. 3 illustrates a substrate in a side view during processing according to a further embodiment of the invention;

FIG. 4 illustrates a substrate and exposure fields in a top view during processing according to a further embodiment of the invention;

FIG. 5 illustrates a substrate and exposure fields in a top view during processing according to a further embodiment of the invention;

FIG. 6 illustrates a lithographic system according to an embodiment of the invention;

FIG. 7 illustrates a lithographic system according to an embodiment of the invention;

FIG. 8 illustrates a lithographic system according to an embodiment of the invention; and

FIG. 9 illustrates a flow chart of method steps according to an embodiment of the invention.

### DETAILED DESCRIPTION OF ILLUSTRATIVE EMBODIMENTS

Embodiments of a photosensitive layer stack for patterning a substrate, and a method and system for patterning a substrate are discussed in detail below. It should be appreciated, however, that the present invention provides many applicable inventive concepts that can be embodied in a wide variety of specific contexts. The specific embodiments discussed are merely illustrative of specific ways and do not limit the scope of the invention.

In the following, embodiments of the photosensitive layer stack, method and system are described with respect to improving overlay accuracy during mask projection of a layer of an integrated circuit. The embodiments, however, might also be useful in other respects, e.g., pattern fidelity of two-dimensional structures or manufacturability of a layer of an integrated circuit.

Furthermore, it should be noted that the embodiments are described with respect to manufacturing integrated circuits. Lithographic mask projection can also be applied during manufacturing of different products, e.g., liquid crystal panels, thin film elements or the like might be produced as well.

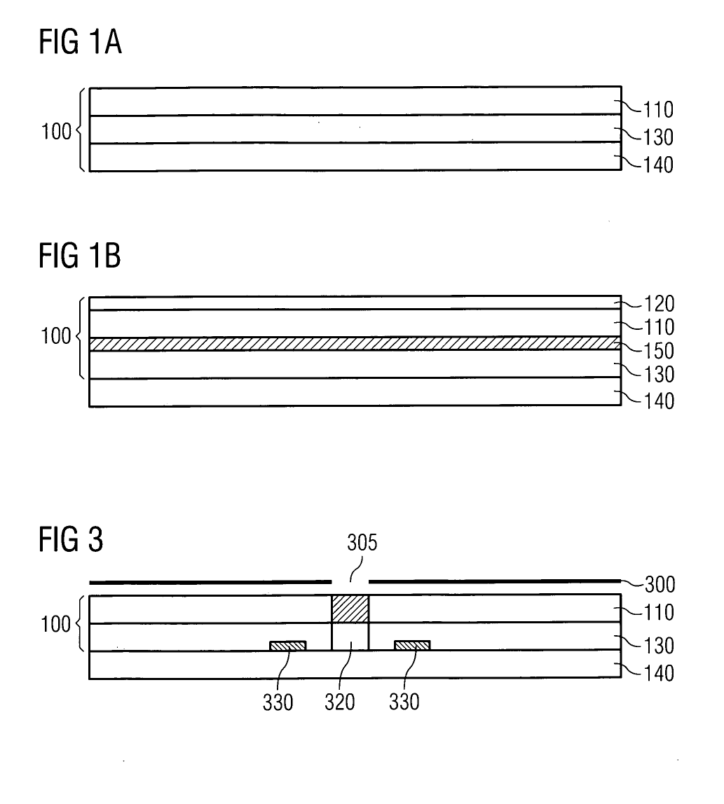

In FIG. 1A, a first embodiment of a photosensitive layer stack is shown. The photosensitive layer stack 100 includes a photochromic layer 110. As shown in FIG. 1A, below the photochromic layer 110, a patterning layer 130 is arranged on a substrate 140. The patterning layer 130 can be a resist film layer with a sensitivity suitable for structuring under actinic light with a wavelength of 193 nm, for example.

It should be noted that the term “photochromic” refers to an absorption property of layer 110 where the absorption in a certain spectral range changes under irradiation in a second spectral range. This behavior can either be from initially transmissive to absorptive or from initially absorptive to transmissive and is known in the art as photochromic effect. Suitable materials will be discussed below.

The absorption of photochromic layer 110 can be based on a reversible or irreversible photochromic effect such that after irradiation with actinic electromagnetic radiation, i.e., radiation for which the resist film layer is sensitive, the absorption changes in a spectral range suitable for optical overlay measurements. More specifically, irradiation can include exposure with electromagnetic radiation with a wavelength below 250 nm. The optical overlay measurement can include illumination with electromagnetic radiation having a wavelength above 250 nm.

When describing embodiments related to photolithographic structuring, any kind of lithographic projection apparatus using a wide range of different feasible illumination wavelengths can be used. Within the described embodiments, a projective optical system using a UV light source of 193 nm is employed. However, other wavelengths like 248 nm, 157 nm or extreme ultraviolet (EUV) are not excluded. Furthermore mask projection means employing all kinds of projection systems having a certain demagnification but also including proximity projection, reflective projection or the like. Furthermore, high NA systems like immersion lithography systems can also be employed. For a person skilled in the art it is known that a projection optic is usually provided in order to project the first pattern of the structuring device onto the substrate 140 including a demagnification of 4 to 5, for example.

The term “substrate” includes semiconductor wafers having an already structured layer or already structured layer systems being arranged partially or fully covering the substrate. Silicon, germanium or gallium arsenide either doped or undoped are suitable materials. However, other materials of semiconductor wafers are not excluded. Furthermore other substrates like glass, plastic or the like are also within the scope of the term “substrate.”

According to a further embodiment (not shown), the photosensitive layer stack 100 includes the photochromic layer 110 and the patterning layer 130. Different to the previous embodiment, the patterning layer 130 is arranged above the photochromic layer 110. According to this embodiment, the photochromic layer 110 is arranged above the substrate 140. It is also conceivable that the photochromic layer 110 is embedded into patterning layer 130.

It should be noted that in the embodiment depicted in FIG. 1A (and also in the following embodiments) patterning layer 130 can be either a positive or negative type resist, for example.

A further embodiment is shown with respect to FIG. 1B. As shown in FIG. 1B, a first interface layer 120 can be arranged above the photochromic layer 110. A second interface layer 150 can be arranged between the photochromic layer 110 and the patterning layer 130. The second interface layer 150 serves as a barrier between the pair of photochromic layer 110 and patterning layer 130 in order to allow for unaltered optical behavior during deposition of photochromic layer 110 and patterning layer 130, improved adhesion of the individual layers of layer stack 100 or anti-reflective coating. Furthermore, the first interface layer 120 and the second interface layer 150 can serve as a chemical barrier such that the individual characteristics of the individual layers of layer stack 100 remain constant or change only weakly after deposition.

In general, the photosensitive layer stack 100 with or without the first interface layer 120 and the second interface layer 150 can include composites being soluble in a solvent, for example, water or a resist developer solution. However, when employing immersion lithography, photochromic layer 110 can include composites that are not soluble in water or other immersion liquids in order to serve as a top coating for immersion lithography. Furthermore, first interface layer 120 can serve as a top coating for immersion lithography as well.

In addition, the photochromic layer 110 can be capable for enhancing image contrast during a mask projection, i.e., the photochromic layer 110 can serve as a contrast enhancing layer known as CEL in the art.

The photochromic layer 110 includes composites having photochromic characteristics, for example, compounds like Vulgin, Spiroxazine, and Chrome. It is also possible to use nano-sized particles which include copper, silicon, germanium, and their various isomers, alloys or oxides.

Using the reversible photochromic effect an absorption change from initially transmissive to absorptive is followed by a return to the transparent state after a certain time.

In case of irreversible photochromic effect, the photochromic layer 110 stays in the absorptive state. Furthermore, any intermediate behavior including for example a partial absorption without fully recovering into the initial transmissive state is considered to be within the scope of the term “photochromic.”

According to embodiments of the invention, the patterning layer 130 and the photochromic layer 110 are subjected to consecutive exposure steps. In a first step, an overlay target is projected onto the photochromic layer 110. After inspecting the overlay target, e.g., by measuring an overlay error between the overlay target within the photochromic layer 110 and an overlay target being already formed within the substrate 140, an correction offset can be calculated based on the measurement of the overlay error.

Using this correction offset allows performing a correction of a wafer stage so as to reduce overlay errors during subsequent exposure steps. Accordingly, a second mask projection can be performed so as to print a pattern onto the patterning layer 130 with reduced overlay errors.

In general, absorption of the photochromic layer 110 switches from transmissive to absorptive or from absorptive to transmissive upon irradiation with electromagnetic radiation during the first and/or the second mask projection under which the resist film layer is sensitive.

In a first example, an irradiation can be performed with a wavelength below 250 nm, i.e., with actinic radiation of 193 nm. Accordingly, the patterning layer 130 is selected such that its spectral sensitivity range is adapted to this exposure step.

Accordingly, substantially no latent image is formed within patterning layer 130 during the first exposure step. The higher sensitivity of the photochromic layer 110 requires only a small exposure dose during the first mask projection, i.e., the exposure dose is much lower than the exposure dose needed to expose patterning layer 130.

In a second example, irradiation can be performed on substrate 140 with a first overlay target using actinic radiation of 193 nm. Different to the previous example it is however also conceivable that a latent image of the second overlay target is formed within patterning layer 130 during the first exposure step. During the second mask projection, a third overlay target can be formed within the patterning layer 130. According to this example, the second overlay target and the third overlay target can be formed on different positions in order to allow determination of the overlay error between the first overlay target and the third overlay target being transferred in the second corrected exposure.

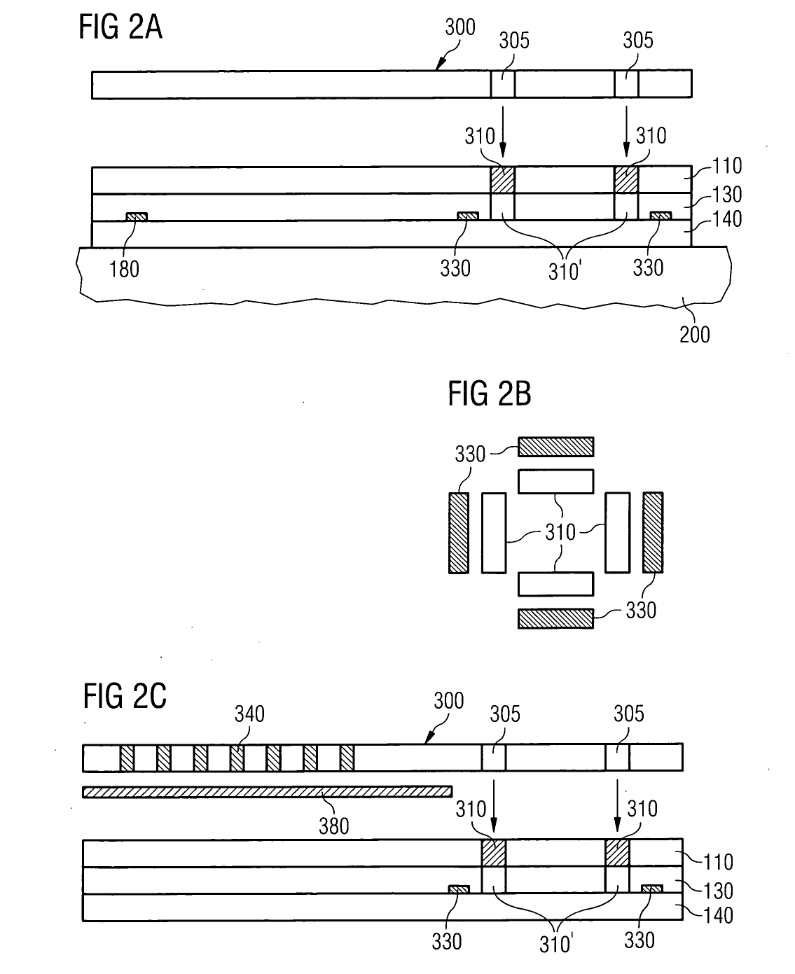

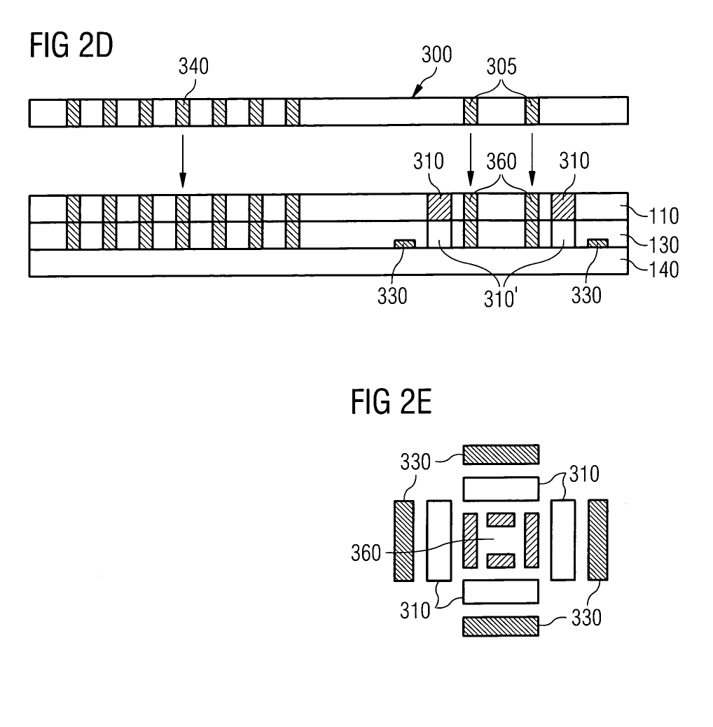

The above described procedures are now further outlined making reference to FIGS. 2A to 2C. In the following, the embodiment according to FIG. 1A is now explained in more detail when performing exposures in an exposure tool. It should be noted that the embodiment according to FIG. 1B can also serve as a starting point for further processing steps.

Making reference to FIG. 2A, the semiconductor wafer or substrate 140 is provided having the patterning layer 130 and the photochromic layer 110 deposited on its surface, e.g., by spin coating or any other suitable deposition technique.

The coated substrate is inserted into an exposure apparatus, e.g., by depositing the coated substrate on a wafer stage 200. Other processing steps, like focusing, alignment procedures or the like, are performed in order to provide full functionality. In order to do so, the substrate 140 is already structured with an alignment mark 180 and a first overlay target 330. The alignment mark 180 is used to provide an alignment of substrate 140 with respect to an optical projection system.

As schematically depicted in FIG. 2A, a first exposure is performed. During the first exposure, a first pattern 305 is projected on the substrate 140. The first pattern 305 is provided on the photo mask 300, which can be a photo mask of any type e.g., Chrome-on-glass, attenuating phase shift or the like. The first pattern 305 includes one or more overlay targets suitable for overlay measurements, e.g., box or line shaped marks. For simplicity, FIG. 2A only depicts the corresponding first pattern 305 when projected on the substrate 140, i.e., the image of the photo mask 300 during mask projection near the substrate 140. In the first exposure step, only overlay targets are projected onto the substrate 140 by using a specific mask 300 as shown in FIG. 2A.

During the first exposure step, the photochromic layer 110 is irradiated by UV-photons in first areas 310, which are not blocked by absorbing elements of the first pattern 305 on corresponding parts of the photo mask 300. As a consequence, the photochromic layer 110 switches from transmissive to absorptive behavior in the first areas 310. As long as the photochromic layer 110 is still transmissive, UV-photons also illuminate the patterning layer 130.

During the transmissive state of photochromic layer 110, UV-photons irradiate the patterning layer 130 in a first area 310′ which corresponds to the first pattern 305. As the sensitivity for patterning layer 130 is selected to be smaller than the sensitivity of photochromic layer 110, only the transmissive state of photochromic layer 110 is changed. In other words, photochromic layer 110 has a much higher sensitivity as compared to the patterning layer 130 so that the exposure state of patterning layer 130 is left almost unaltered. The photochromic layer 110 is provided such that its sensitivity during the first and/or the second mask projection is higher, i.e., by a factor 50, than the sensitivity of the patterning layer 130. In other words, the photochromic layer 110 is selected such that its sensitivity for changing the absorption coefficient of the light used for overlay measurement is higher than the sensitivity of the patterning layer 130.

After the first exposure, an optical overlay measurement is performed. The measurement is performed by inspecting second overlay targets within first areas 310 formed on photochromic layer 110 relative to a respective first overlay target 330 as shown in FIG. 2B. The first overlay target 330 is formed on an already structured layer on substrate 140 in a previous manufacturing step. It is also conceivable that first areas 310 and first overlay target 330 form other types of box-in-box structures or employ a micro pattern, as is known in the art.

After inspecting the overlay targets, e.g., by measuring an overlay error between the second overlay targets in first areas 310 and the first overlay targets 330, correction offsets can be calculated. Using the correction offsets allows performing a correction of the wafer stage exposure positions so as to reduce overlay errors during subsequent exposure steps.

It should be noted that correction offsets can be applied to the wafer stage in different ways. It is possible, for example, to derive a set of correction offsets for each exposure. However, it is also possible to calculate the correction offsets for a group of several, for example adjoining, exposure fields. Furthermore, the correction offsets can be calculated for different radial positions of exposure fields on the substrate 140. Other conceivable options include extrapolating between different exposure fields or the like.

In the first exposure step, only overlay targets have been projected onto the substrate 140 by using a specific mask 300 as shown in FIG. 2A. It is also conceivable to provide blades 380 to shadow other parts of the full patterned mask (as schematically shown in FIG. 2C) when viewing the photochromic layer 110 from a top view.

For overlay error measurement, light of a wavelength being different from the wavelength of the radiation being used during the first mask projection (actinic light) can be employed. The spectral range of the light used for overlay measurement can be selected such that the patterning layer 130 is not exposed during optical overlay error measurement, i.e., it is not exposed when performing optical overlay error measurement.

After completion of the first exposure with the second overlay target, a second exposure using a second pattern is performed. A second pattern can be a pattern suitable of forming a required layout pattern on the substrate 140 within patterning layer 130. The patterning layer 130 can in the following steps be patterned by applying the correction offsets in order to reduce overlay errors. It should be noted that the first mask projection and the second mask projection are performed without removing the substrate 140 from the wafer stage.

It should be noted that the first and second patterns are formed in different areas on the substrate 140. As the patterning layer 130 is not exposed during the first mask projection, a third overlay target 360 is now projected into the patterning layer 130. The third overlay target 360 can be useful for further mask projection steps. Furthermore, the third overlay target 360 can be arranged in a different region with respect to the second overlay target. As shown in FIG. 2E, the third overlay target 360 (FIG. 2D) is arranged so as to surround both the first overlay target 330 and the second overlay target in areas 310.

In summary, the first pattern 305 including overlay targets in areas 310 and the second pattern including a product pattern 340 can be arranged on different areas of a single photo mask 300, as shown in FIG. 2C. It is, however, also conceivable that the first pattern 305 is arranged on a first photo mask 300 as shown in FIG. 2A and the second pattern is arranged on a second photo mask. The first photo mask 300 can be replaced by the second photo mask after performing the first exposure. It should be noted that substrate 140 still remains on the wafer stage. Accordingly, no additional alignment or adjustment steps are necessary for substrate 140.

It should be mentioned that the mask alignment can be performed with a much higher accuracy in comparison to a wafer stage alignment. More specifically, according to demagnification of the optical projection system the residual error is reduced on the substrate. Furthermore, it should be noted that possible placement errors on the mask or between the masks can be corrected by appropriate offsets.

Processing continues by removing the photochromic layer 110. This can be performed either in a single step or in different steps or employing intermediate processing steps for enabling the removal of the photochromic layer 110. In addition, a post-exposure-bake can be performed so as to stabilize the latent image in the resist film layer 130.

Following this, a development process of the resist film layer or patterning layer 130 can be performed. The resulting resist structure is then used for structuring an underlying layer in substrate 140 or as a mask for an implantation step or for any other process sequence which might be necessary for further processing the substrate 140.

In general, the spectral absorption properties of the photosensitive layer stack 100 are adapted to the exposure characteristics of an appropriate resist film material for patterning layer 130, i.e., by taking into account exposure dose threshold and sensitivity range.

In the previous embodiments, it has been described that photochromic layer 110 switches from transmissive to absorptive upon irradiation with electromagnetic radiation. It is also conceivable that the transmission change is reversible, i.e., slowly returns back to the transmissive state after the first mask projection has been performed. In order to allow optical overlay error measurement as described above, a further treatment of photochromic layer 110 can be performed in order to stabilize its transmission change or enlarge its absorption change.

This treatment can include affecting the photochromic layer 110 with a gas or a liquid, performing a wait cycle for a predetermined time following the first irradiation, or performing a thermal cycle, i.e., by heating the layer stack 100 with an appropriate thermal source such as an infrared source, for example. Furthermore, this treatment can be an irradiation with the different electromagnetic radiation as used during the first exposure step. For example, the light used for optical overlay error measurement can be used to stabilize photochromic layer 110.

A further embodiment is now illustrated making reference to FIG. 3. In this embodiment, the semiconductor wafer or substrate 140 is provided having the patterning layer 130 and the photochromic layer 110 deposited on its surface, e.g., by spin coating or any other suitable deposition technique. The coated substrate is inserted into an exposure apparatus, e.g., by depositing the coated substrate on a wafer stage.

As depicted in FIG. 3, a first exposure is performed. During the first exposure, a first pattern 305 is projected on the substrate 140. The first pattern 305 is provided on a photo mask device 300, which can be a photo mask of any type, e.g., chrome-on-glass, attenuating phase shift or the like. The first pattern 305 includes structures suitable for overlay measurements, e.g., box or line shaped marks. For simplicity, FIG. 3 only depicts the corresponding first pattern 305 when projected on the substrate 140.

During the first exposure, the photochromic layer 110 is irradiated by UV-photons in first areas 310 which are not blocked by absorbing elements of the first pattern 305 on corresponding parts of the photo mask 300. As a consequence, the photochromic layer 110 switches from transmissive to absorptive behavior in the first areas 310. As long as the photochromic layer 110 is still transmissive, UV-photons also illuminate the patterning layer 130.

During the transmissive state of photochromic layer 110, UV-photons expose the patterning layer 130 and also a first area 320 which corresponds to the first pattern 305. As photochromic layer 110 and patterning layer 130 have a similar sensitivity under actinic radiation, a latent image on patterning layer 130 is formed which corresponds to the first pattern 305.

After inspecting the overlay target, e.g., by measuring an overlay error between the overlay target 320 and the first areas 310, correction offsets can be calculated based on the optical overlay measurement of the overlay error. Using the correction offsets, correction of the wafer stage exposure positions may be performed so as to reduce overlay errors during subsequent exposure steps.

After completion of the first exposure with the second overlay target, a second exposure using a second pattern is performed. The second pattern can be a pattern suitable of forming a required layout pattern on the substrate 140 within patterning layer 130. It should be noted that the first pattern 305 exposes the patterning layer 130 during the first mask projection with the second overlay target.

In the second exposure step, a product pattern and a third overlay target 330 are now projected into the patterning layer 130. The third overlay target 330 can be printed next to the second overlay target in order to monitor the reduction of overlay errors. Furthermore, the third overlay target 330 can be arranged in a different region with respect to the second overlay target.

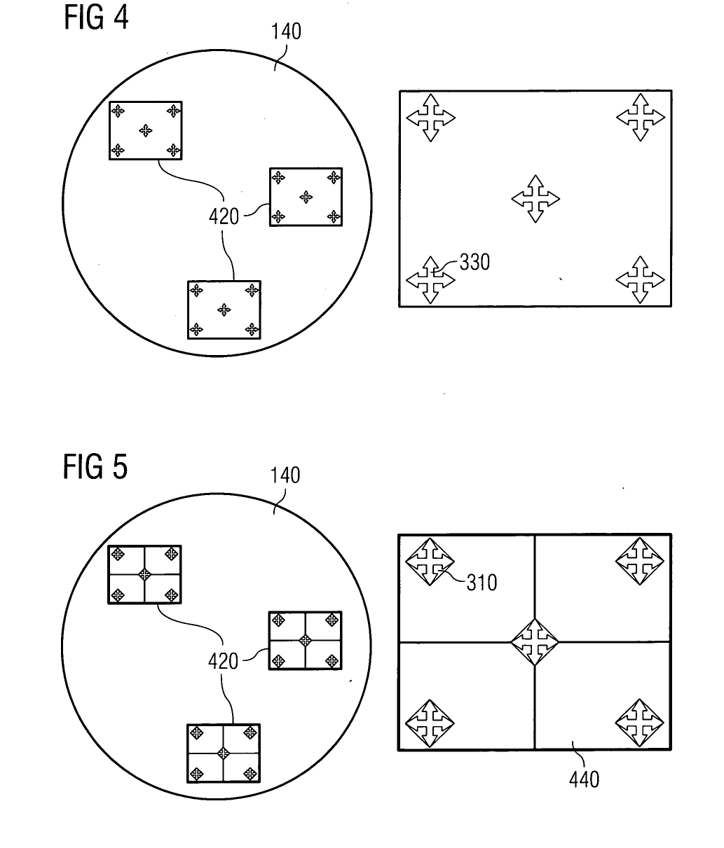

Making reference to FIG. 4, the substrate 140 is shown in a top view. As explained above, the substrate 140 is structured with a previous layer so as to form overlay targets 330. As known in the art, mask projection is usually performed in exposure fields, which are juxtaposed on the surface of substrate 140. In FIG. 4, only a few exposure fields 420 are shown for simplicity.

In FIG. 5, the substrate 140 is shown in a top view after having performed the first and the second exposures. First areas 310 are formed next to overlay targets 330 (see FIG. 4). Outside the region used for the overlay marks, the second pattern 440 is formed during the second exposure.

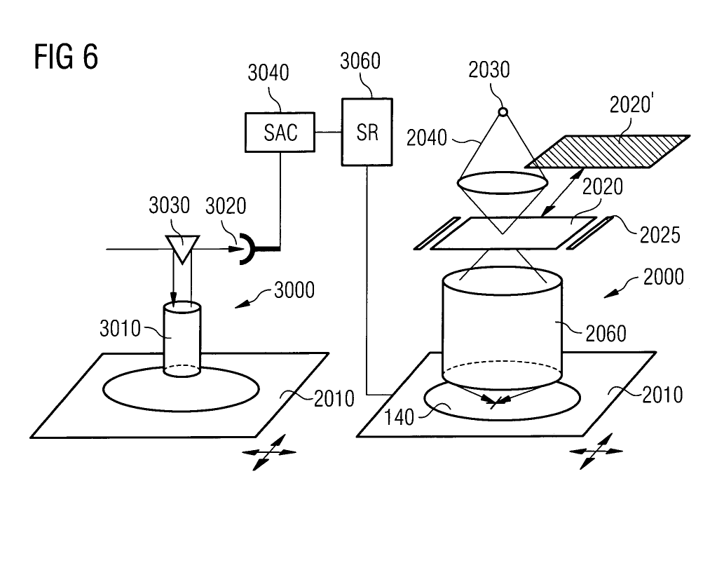

In FIG. 6, an embodiment of a lithographic system for lithography is depicted including a lithographic projection apparatus 2000 with a wafer stage 2010 and a photo mask 2020 insertable into a mask holder 2025. The substrate 140 is arranged on the wafer stage 2010 and includes the layer stack 100 with the photochromic layer 110 deposited on the resist film (see FIG. 1A).

The projection apparatus 2000 furthermore includes a light source 2030, which is, e.g., an Excimer laser with 193 nm wavelength, for example. An illumination optic 2040 projects the light coming from the light source 2030 through the photo mask 2020 into a projection system 2060. The photo mask 2020 can include the first pattern and the second pattern, which can be arranged on different areas of a single photo mask. It is, however, also conceivable that the first pattern is arranged on a first photo mask and the second pattern is arranged on a second photo mask.

The first photo mask 2020 can be replaced by the second photo mask 2020′ after performing the first exposure, as shown in FIG. 6. As mentioned above, positioning errors between the mask features of the first photo mask 2020 and the second photo mask 2020′ are relatively small and/or can be attributed by appropriate offsets.

Accordingly, substrate 140 remains on the wafer stage 2010 of the lithographic projection apparatus 2000 during a first exposure, overlay measurement and a second exposure, and no additional alignment or adjustment steps are necessary for substrate 140.

Next to lithographic projection apparatus 2000, an optical overlay error measurement tool 3000 is shown, which is capable of measuring overlay errors. The optical overlay error measurement tool 3000 includes optical units 3010, 3030 for imaging, a detector 3020 for optical scanning of overlay targets and a processor or computing device 3040 for performing pattern recognition and calculating overlay errors.

From measured overlay errors correction offsets are calculated using the computing device 3040. The calculated correction offsets are applied to a stage control 3060. It should be noted that substrate 140 remains on wafer stage 2010 when performing optical overlay error measurement. According to this embodiment, optical overlay error measurement is performed outside the exposure area of lithographic projection apparatus 2000.

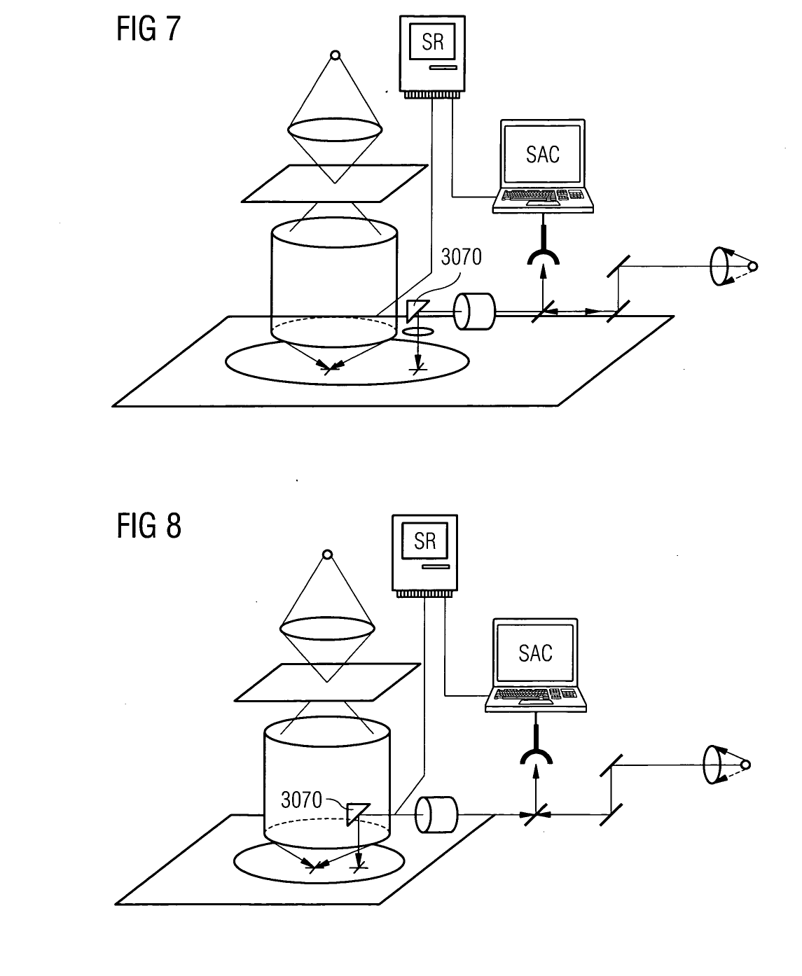

In FIG. 7, a further embodiment of a lithographic system is depicted. In addition to the elements already described with respect to FIG. 6, optical overlay error measurement of overlay targets is performed while the substrate 140 is arranged close to the projection lens 3070, which allows exposure and optical overlay error measurement simultaneously. In order to do so, optical unit 3010 images the overlay targets to the optical sensor. Optical unit 3010 can be movable in at least two dimensions so as to be adjusted to the appropriate measurement position.

In FIG. 8, a further embodiment of a lithographic system is depicted. In addition to the elements already described with respect to FIG. 6 and FIG. 7, optical overlay error measurement of overlay marks is performed through parts of the projection lens 3070 when substrate 140 is arranged underneath the projection optics. Again, optical unit 3010 is movable in at least two dimensions so as to be adjusted to the appropriate measurement position

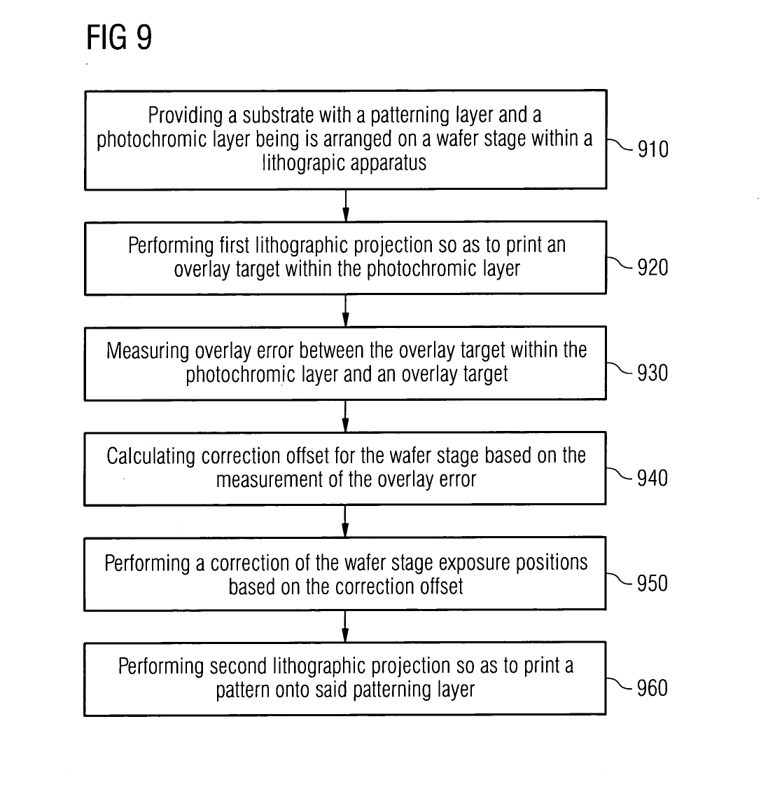

In FIG. 9, method steps for patterning a substrate are depicted in a flow diagram.

In step 910, a work piece or substrate with a patterning layer and a photochromic layer arranged on a wafer stage within a lithographic apparatus is provided.

In step 920, a first mask projection is performed so as to print an overlay target within the photochromic layer.

In step 930, an overlay error is measured between the overlay target within the photochromic layer and an overlay target arranged within the work piece.

In step 940, a correction offset is calculated for the wafer stage based on the measurement of the overlay error.

In step 950, a correction of the wafer stage exposure positions based on the correction offset is performed.

In step 960, a second mask projection is performed so as to print a pattern onto the patterning layer.

Having described embodiments of the invention, it is noted that modifications and variations can be made by persons skilled in the art in light of the above teachings. It is therefore to be understood that changes may be made in the particular embodiments of the invention disclosed which are within the scope and spirit of the invention as defined by the appended claims. What is claimed and desired to be protected by Letters Patent is set forth in the appended claims.

What is claimed is:

1. A method of patterning a substrate, the method comprising:
providing a substrate with an alignment mark and a first overlay target, the substrate being arranged on a wafer stage within a lithographic apparatus;
coating the substrate with a photosensitive layer stack including a patterning layer and a photochromic layer;
performing an alignment of the substrate using the alignment mark relative to a first mask for a first mask projection of the first mask so as to print first mask features including a second overlay target within the photochromic layer;
measuring an overlay error between the first and the second overlay targets;
calculating a correction offset of the wafer stage based on the measurement of the overlay error; and
performing a second mask projection applying the correction offset so as to print a pattern onto the patterning layer, wherein the first mask projection and the second mask projection are performed without removing the substrate from the wafer stage.

2. The method according to claim 1, wherein the first mask projection comprises changing a transmittance of the photochromic layer.

3. The method according to claim 2, wherein the photochromic layer changes the transmittance from transmissive to absorptive in a spectral range suitable for optical overlay error measurement.

4. The method according to claim 3, wherein the photochromic layer is substantially insensitive for radiation having a wavelength that is different than a wavelength used during the first and/or the second mask projections.

5. The method according to claim 1, wherein measuring the overlay error comprises performing optical overlay error measurement with radiation having a wavelength that is different than a wavelength used during the first and/or the second mask projections.

6. The method according to claim 2, wherein changing a transmittance of the photochromic layer is performed and/or further enhanced by applying a further treatment, the further treatment comprising a treatment selected from the group consisting of: (1) affecting the photochromic layer with a gas or a liquid, (2) performing a thermal cycle of the photochromic layer, (3) performing a wait cycle for a predetermined time following the first mask projection, and (4) performing a further irradiation having a wavelength that is different than the wavelength used during the first and/or the second mask projections.

7. The method according to claim 6, wherein the further treatment changes the transmittance in a spectral range suitable for optical overlay measurement.

8. The method according to claim 1, wherein the first mask includes mask features comprising the second overlay target in a first region and a product pattern in a second region, the second region being blocked by blades during the first mask projection.

9. The method according to claim 1, wherein the first mask includes mask features comprising the second overlay target and a second mask includes a mask features pattern in a second region, the first mask being exchanged by the second mask for the second mask projection.

10. The method according to claim 1, wherein the photochromic layer is provided with a sensitivity for changing an absorption coefficient of a light used for measuring the overlay error that is higher than a sensitivity of the patterning layer.

11. The method according to claim 9, wherein the first and/or the second mask projections comprise irradiation with electromagnetic radiation having a wavelength below 250 nm and wherein measuring the overlay error comprises illumination with electromagnetic radiation having a wavelength above 250 nm.

12. The method according to claim 1, wherein the photochromic layer is capable of enhancing image contrast during the second mask projection.

13. The method according to claim 1, wherein the first mask projection and the second mask projection are performed using an immersion lithography apparatus.

14. A photosensitive layer stack for patterning a substrate in a lithographic projection system, the photosensitive layer stack comprising:
a photo resist layer and a photochromic layer arranged above the substrate that includes a first overlay target and an alignment mark; and
a second overlay target arranged within the photochromic layer, wherein the substrate is arranged on a wafer stage in the lithographic projection system capable of at least partially compensating an overlay error between the first and the second overlay targets after alignment by using the alignment mark.

15. The photosensitive layer stack according to claim 14, wherein the photochromic layer serves as a top coating during immersion lithography.

16. The photosensitive layer stack according to claim 14, further comprising a first interface layer below the photochromic layer and a second interface layer above the photochromic layer.

17. The photosensitive layer stack according to claim 14, wherein the photochromic layer is embedded into the photo resist layer.

18. A lithographic system, comprising:
an imaging system capable of imaging a photo mask including a pattern of a first overlay target;
a movable stage arranged under the imaging system, the movable stage configured to hold a substrate, the substrate comprising a photosensitive layer including a patterning layer and a photochromic layer and further comprising an alignment mark and the first overlay target arranged within the substrate;
an alignment unit capable of aligning the substrate by using the alignment mark;
an optical overlay measurement unit configured to measure an overlay error between the first overlay target and a second overlay target imaged onto the photochromic layer by using the photo mask; and
a control unit capable of calculating a correction offset of exposure positions of a wafer stage based on the measurement of the overlay error.

19. The lithographic system according to claim 18, wherein the optical overlay measurement unit is configured to measure the overlay error in a position of the substrate that is different than a position during exposure of the substrate.

20. The lithographic system according to claim 18, wherein the optical overlay measurement unit is configured to measure the overlay error in a position of the wafer stage that is substantially identical to a position during exposure of the substrate.

21. The lithographic system according to claim 20, wherein the optical overlay measurement unit and the imaging system share optical components.

22. A method of patterning a substrate using a lithographic apparatus, the method comprising:
providing a substrate with a photosensitive layer including a patterning layer and a photochromic layer disposed above the substrate, the substrate arranged on a wafer stage within a lithographic apparatus and comprising an alignment mark and a first overlay target;
performing an alignment of the substrate using the alignment mark relative to a first mask for a first mask projection of that first mask so as to print first mask features within the photochromic layer, the first mask features including a second overlay target;
measuring an overlay error between the first and the second overlay targets;
calculating a correction offset based on the measurement of the overlay error; and
performing a second mask projection so as to print a pattern onto the patterning layer, wherein the overlay error measurement, the first mask projection and the second mask projection are performed by using the correction offset to correct wafer stage exposure positions and without removing the substrate from the wafer stage.

23. A method of patterning a substrate, the method comprising:
providing a substrate with an alignment mark and a first overlay target, the substrate being arranged on a wafer stage within a lithographic apparatus;
coating the substrate with a photosensitive layer stack that includes a patterning layer and a photochromic layer;
providing a photo mask, the photo mask having mask features including a second overlay target;
aligning the substrate relative to the photo mask using the alignment mark;
performing a first mask projection of the photo mask so as to print substantially only the second overlay target within the photochromic layer;
measuring an overlay error between the first and the second overlay targets;
calculating a correction offset of the wafer stage based on the measurement of the overlay error;
applying the correction offset to the wafer stage so as to correct wafer stage exposure positions; and
performing a second mask projection with the correction offset so as to print a full pattern content onto the patterning layer, wherein the first mask projection and the second mask projection are performed without removing the substrate from the wafer stage.

24. The method according to claim 23, wherein, between the first mask projection and the second mask projection, the photo mask is exchanged by providing a further mask including the full pattern content.

25. The method according to claim 24, wherein the full pattern content is provided by the photo mask and the photochromic layer is provided having a sensitivity used during the first mask projection and/or the second mask projection that is higher than a sensitivity of the patterning layer.
